(19) United States
(12) Patent Application Publication
(10) Pub. No.: US 2008/0113512 A1
(43) Pub. Date: May 15, 2008

(54) METHOD OF FABRICATING ISOLATION LAYER OF SEMICONDUCTOR DEVICE

(75) Inventor: Myoung Shik KIM, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/857,482

(22) Filed: Sep. 19, 2007

(30) Foreign Application Priority Data
Nov. 9, 2006 (KR) 10-2006-0110467

(51) Int. Cl. H01L 21/304

(52) U.S. Cl. 438/692; 257/E21.237

(57) ABSTRACT

A method of fabricating isolation layers of a semiconductor device is provided. The method includes depositing a pad oxide layer and a hard mask in sequence on a semiconductor substrate and patterning the pad oxide layer and the hard mask. Trenches may be formed by etching the substrate to a specific depth and a gap-fill insulating layer may be formed in the substrate in which the trenches have been formed. The method further includes forming a barrier layer on the gap-fill insulating layer in a region where a pattern density of an isolation layer is relatively low, then polishing and removing the gap-fill insulating layer and the barrier layer until a top surface of the hard mask is exposed. Consequently, isolation layers are gap-filled only in the trenches, yielding a regular surface on the semiconductor substrate.

### CROSS-REFERENCE TO RELATED APPLICATION

This application claims priority to Korean Application No. 10-2006-0110467, filed on Nov. 9, 2006, which is incorporated herein by reference in its entirety.

### BACKGROUND

1. Field of the Invention

The present invention relates to a method of fabricating semiconductor devices; and, more particularly, to a method of fabricating isolation layers of a semiconductor device that prevents etch irregularity. Etch irregularity is due to a difference in the density of isolation layer patterns when polishing a shallow trench isolation (STI) layer.

2. Background of the Invention

In view of the large-scale integration of semiconductor devices, a reduction in device size and line width has become increasingly indispensable. Thus, a technique of shrinking isolation layers for isolating elements has emerged as one of the important factors in semiconductor device manufacturing.

To this end, an STI isolation layer structure has been widely used to form the isolation layers of semiconductor devices. A STI fabrication process is a process of forming a shallow trench in a semiconductor substrate with a specific depth, gap-filling the trench with an insulating layer by chemical vapor deposition (CVD), and polishing the insulating layer by a chemical mechanical polishing (CMP) process, thus forming an isolation layer for isolating an active region from an inactive region.

FIGS. 1A to 1D are vertical cross-sectional views illustrating a conventional method of fabricating isolation layers of a semiconductor device. In FIGS. 1A to 1D, reference numeral A indicates a dense region in which the pattern density of an isolation layer is high, and B indicates an isolated region in which the pattern density of an isolation layer is low.

Referring first to FIG. 1A, a pad oxide layer 12 and a silicon nitride (SiN) layer 14 (i.e., a hard mask) are sequentially deposited on a semiconductor substrate, such as silicon substrate 10. A moat pattern (not shown), for example, a photoresist pattern, is formed on the SiN layer 14. A dry etch process using the moat pattern as an etch-stop layer is performed to pattern the SiN layer 14 and the pad oxide layer 12.

Referring to FIG. 1B, the silicon substrate 10 exposed by the patterned SiN layer 14 and the patterned pad oxide layer 12 is etched to a specific depth, forming trenches 16. The moat pattern on the SiN layer 14 is then removed.

Referring to FIG. 1C, a gap-fill insulating layer 18 for gap-filling the trenches is deposited on the entire surface of the silicon substrate 10 by a CVD process, thereby completely gap-filling the trenches. The deposition process employs, for example, a low pressure (LP)-CVD process of depositing tetra ethyl ortho silicate (TEOS) at low pressure, an atmospheric pressure (AP)-CVD of depositing TEOS and ozone at atmospheric pressure, a sub-atmospheric (SA)-CVD process of depositing TEOS and ozone at sub-atmospheric pressure or less, or a high density plasma (HDP)-CVD process of depositing a silicon oxide layer. In recent years, in order to overcome variations in the pattern density, high selectivity slurry including silica or a certain abrasive and an additive is used during the deposition of the gap-fill insulating layer 18.

Referring to FIG. 1D, a CMP process using the SiN layer 14 as a buffer layer is performed to polish the gap-fill insulating layer, thus forming isolation layers 18a only within the trenches.

Though not illustrated in the drawings, the SiN layer and the pad oxide layer remaining on the silicon substrate 10 are removed, thus completing the fabrication process of the trench isolation layers.

However, an irregularly polished surface may result when, for example, the gap-filling insulating layer 18 is applied unevenly. According to conventional fabrication processes, when the semiconductor device includes a logic circuit, dummy isolation layers can be formed in regions with device patterns of well, resistor and capacitor characteristics.

Thus, the gap-fill insulating layer 18 is deposited relatively thickly in the region A where the pattern density is relatively high, but the gap-filling of the gap-fill insulating layer 18 is thin in the region B in which the pattern density is relatively low. The uneven deposition of the gap-filling insulating layer 18 is due to the difference in the pattern density between the region in which the pattern density of the isolation layer is relatively high (heightened in part by dummy isolation layers) and the region in which the pattern density of the isolation layer is relatively low in the semiconductor substrate.

Consequently, as shown in FIG. 2, when the gap-fill insulating layer 18 is polished according to a conventional method, etching is irregularly performed (refer to reference numeral 20) between the regions A and B in which the pattern densities of the isolation layers differ. Accordingly, the whole surface of the substrate is not polished with a regular or smooth profile, which reduces yield in the manufacturing of semiconductor devices with isolation layers.

### SUMMARY OF SOME EXAMPLE EMBODIMENTS

In general, example embodiments of the invention relate to a method of fabricating isolation layers of a semiconductor device, the method preventing etch irregularity of a gap-fill insulating layer due to the difference in the density of isolation layer patterns. The method includes adding a barrier layer on a gap-fill insulating layer in a region of relatively low isolation layer pattern density and performing a polishing process on each layer.

In accordance with one example embodiment, a method of fabricating isolation layers of a semiconductor device includes depositing a pad oxide layer and a hard mask in sequence on a semiconductor substrate and patterning the pad oxide layer and the hard mask. The substrate is then etched to a specific depth to form trenches and a gap-fill insulating layer is formed in the trenches of the substrate. The method further includes forming a barrier layer on the gap-fill insulating layer in a region where a pattern density of an isolation layer is relatively low and then polishing and removing the gap-fill insulating layer and the barrier layer until a top surface of the hard mask is exposed thus forming isolation layers gap-filled only in the trenches.

### BRIEF DESCRIPTION OF THE DRAWINGS

Aspects of example embodiments of the invention will become apparent from the following description of example embodiments given in conjunction with the accompanying drawings, in which:

FIGS. 1A to 1D are vertical cross-sectional views illustrating a conventional method of fabricating isolation layers of a semiconductor device;

FIG. 2 is a vertical cross-sectional view showing planarization failure of a gap-fill insulating layer, which occurs in the process of forming isolation layers having regions of a high pattern density and regions of a low pattern density in the prior art; and

FIGS. 3A to 3G are vertical cross-sectional views illustrating a method of fabricating isolation layers of a semiconductor device in accordance with an embodiment of the present invention.

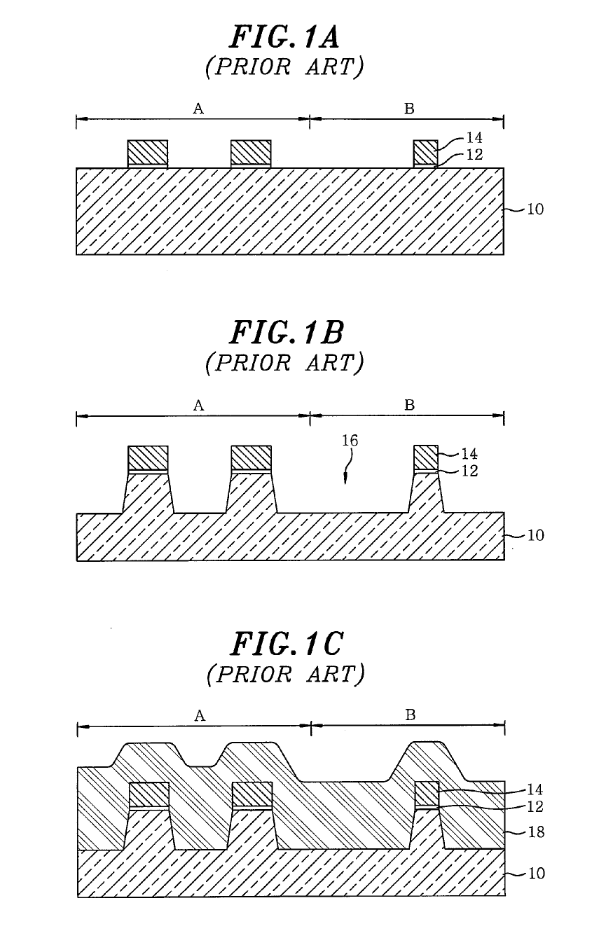

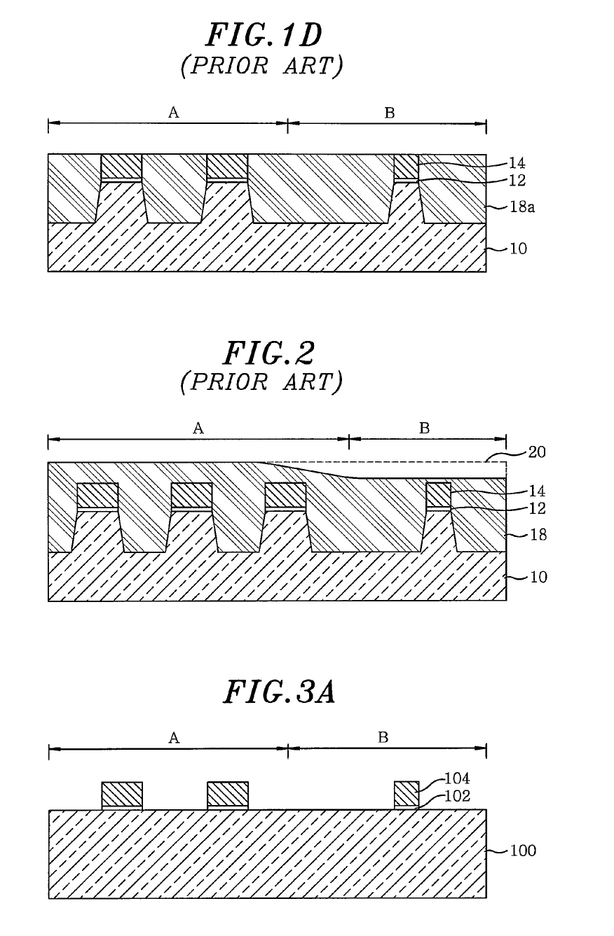

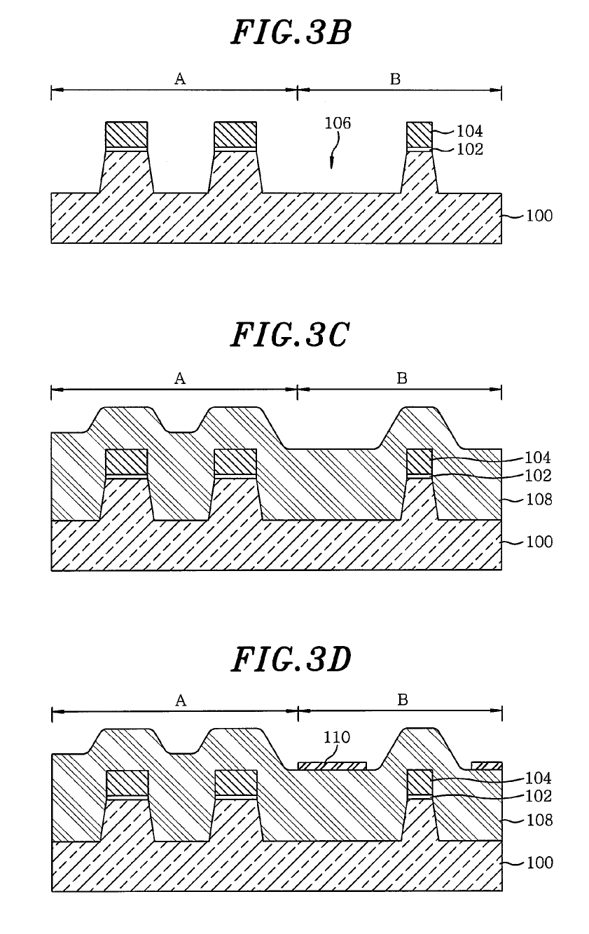

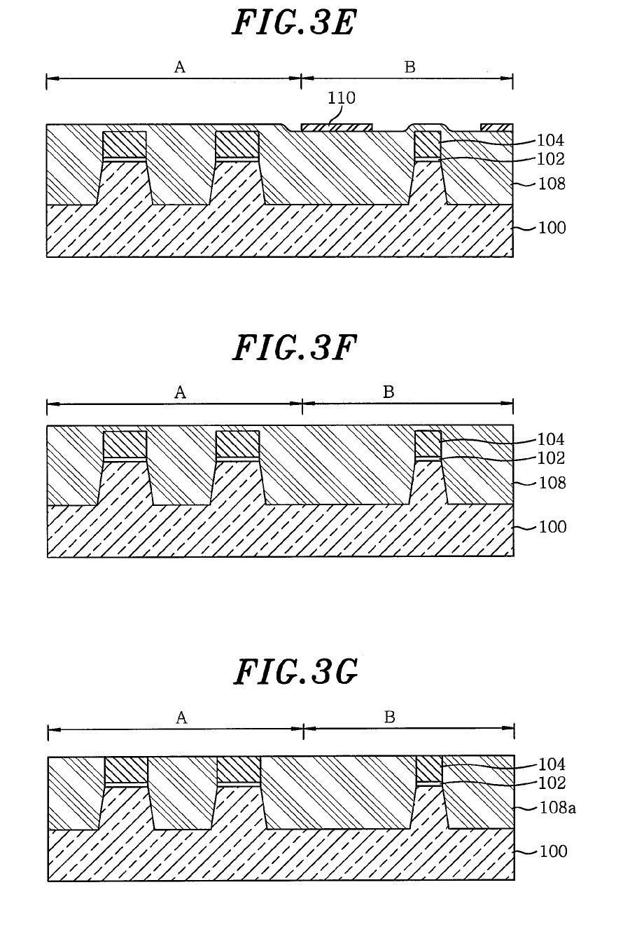

### DETAILED DESCRIPTION OF SOME EXAMPLE EMBODIMENTS

Hereinafter, aspects of example embodiments of the present invention will be described in detail with reference to the accompanying drawings so that they can be readily implemented by those skilled in the art.

FIGS. 3A to 3G are vertical cross-sectional views illustrating a method of fabricating isolation layers of a semiconductor device in accordance with example embodiments of the present invention.

In FIGS. 3A to 3G, reference numeral A indicates a region in which the density of an isolation layer pattern is high and B indicates a region in which the density of an isolation layer pattern is low.

First, referring to FIG. 3A, a pad oxide layer 102 and a hard mask, such as SiN layer 104, may be sequentially deposited on a silicon substrate 100 or any suitable semiconductor substrate.

A moat pattern (not shown) for defining an isolation region, for example, a photoresist pattern, may be formed on the SiN layer 104. A dry etch process using the moat pattern as an etch-stop layer may be performed to pattern the SiN layer 104 and the pad oxide layer 102.

Referring to FIG. 3B, the silicon substrate 100, exposed by the patterned SiN layer 104 and the patterned pad oxide layer 102, may be etched to a specific depth, forming trenches 16. The moat pattern on the SiN layer 104 may then be removed.

Referring to FIG. 3C, a gap-fill insulating layer 108 for gap-filling the trenches may be deposited on a portion of or on the entire surface of the silicon substrate 100 by a CVD process, thereby completely gap-filling the trenches. The deposition process may employ, for example, a LPCVD process of depositing TEOS at low pressure, an APCVD of depositing TEOS and ozone at atmospheric pressure, a SACVD process of depositing TEOS and ozone at sub-atmospheric pressure or less, or a HDP-CVD process of depositing a silicon oxide layer. In recent years, in order to overcome variation in the pattern density, high selectivity slurry including silica or a certain abrasive and an additive may be used when depositing the gap-fill insulating layer 108.

Referring to FIG. 3D, an insulating substance having an etch selectivity with respect to the gap-fill insulating layer 108 may be deposited as a barrier layer 110 on the gap-fill insulating layer 108. The barrier layer 110 may be patterned such that the barrier layer 110 remains on the surface of the gap-fill insulating layer 108 in the region B where the pattern density of the isolation layer is low while being removed from the region A where the pattern density of the isolation layer is high. In this case, the barrier layer 110 can be deposited to a thickness of about 50 Å to 100 Å by using SiN deposited by means of, for example, a plasma-enhanced (PE)-CVD process. The region B in which the pattern density of the isolation layer is relatively low is a dummy blocking region where a dummy isolation layer pattern cannot be formed and may include an area of at least 400×400 μm during a design phase. In addition or alternatively, the region B where the barrier layer 110 is formed may include, for example, a region in which the isolation layer pattern density is 10% or less in the case of a 500×500 μm unit, and/or a region where a width of the isolation layer pattern is 1 μm or less.

Referring next to FIG. 3E, a first CMP process, as a polishing process, may be performed to polish the gap-fill insulating layer 108. At this stage, in regard to an etch target, the gap-fill insulating layer 108 may be etched until the height of the top surface of the gap-fill insulating layer 108 from the bottom surface of the silicon substrate 100 reaches that of the barrier layer 110 or slightly lower/higher. The first CMP process may employ low-selectivity slurry and can be performed so that a gap-fill insulating layer removing rate of the slurry ranges from 3000 Å/min to 3500 Å/min. That is, the first CMP process can be performed by using low-selectivity slurry whose etch selectivity of a silicon oxide layer (e.g., the gap-fill insulating layer 108) to a SiN layer (e.g., the barrier layer 110) ranges from 3:1 to 4:1.

Referring to FIG. 3F, a second CMP process may be performed to polish the gap-fill insulating layer 108 and the barrier layer 110 until they are removed.

Referring to FIG. 3G, a third CMP process may be performed to polish the gap-fill insulating layer 108 until the top surface of the SiN layer 104 is exposed, so that isolation layers 108a in which the gap-fill insulating layer is gap-filled are formed only within the trenches.

The secondary and tertiary CMP processes may employ high selectivity slurry and can be performed so that a gap-fill insulating layer removing rate of the slurry ranges from 3500 Å/min to 4000 Å/min. For example, the second and the third CMP processes can be performed by using high-selectivity slurry whose etch selectivity of a silicon oxide layer (the gap-fill insulating layer 108) to the SiN layer 104 ranges from 30:1 to 40:1.

Though not illustrated in the drawings, the SiN layer 104 and the pad oxide layer 102 remaining on the silicon substrate 100 may be removed, thus completing the fabrication process of the isolation layers of the trench structure.

Although the method of forming the isolation layer has been described with reference to semiconductor devices in which dummy isolation layers are formed, the method may also be applied to semiconductor devices in which dummy isolation layers are not or cannot be formed. In the latter case a barrier layer may be formed in a region where the gap-fill profile of a gap-fill insulating layer is relatively thin before a polishing process is performed on the gap-fill insulating layer.

As outlined above, the CMP process applied to the gap-fill insulating layer may include three stages. For example, in the first polishing stage a relatively thick portion of a gap-fill insulating layer occurring in a region of high isolation layer pattern density may be removed by using low-selectivity slurry. Thus, a step in the thickness of the gap-fill insulating layer between regions with a different pattern density may be substantially eliminated. In the second polishing stage, the gap-fill insulating layer and a barrier layer may be removed by using high-selectivity slurry. In the third polishing stage, the gap-fill insulating layer may be over-polished by using high-selectivity slurry. Thus, the entire surface of the gap-fill insulating layer can be polished to have a regular (i.e., smooth) profile.

As described above, according to the present invention, after a barrier layer is added on a gap-fill insulating layer in a region where the density of an isolation layer pattern is relatively low, a polishing process may be performed on the gap-fill insulating layer. Accordingly, etch irregularity of the gap-fill insulating layer due to the difference in isolation layer pattern density can be prevented and a manufacturing yield of the isolation layer can be improved.

While the invention has been shown and described with respect to specific embodiments, it will be understood by those skilled in the art that various changes and modifications may be made without departing from the spirit and scope of the invention as defined in the following claims.

What is claimed is:

1. A method of fabricating isolation layers of a semiconductor device, the method comprising:
depositing a pad oxide layer and a hard mask in sequence on a semiconductor substrate and patterning the pad oxide layer and the hard mask;
etching the substrate to a specific depth to form trenches;
forming a gap-fill insulating layer in the substrate in which the trenches have been formed;
forming a barrier layer on the gap-fill insulating layer in a region where a pattern density of an isolation layer is relatively low; and
polishing and removing the gap-fill insulating layer and the barrier layer until the top surface of the hard mask is exposed to form isolation layers gap-filled only in the trenches.

2. The method of claim 1, wherein the barrier layer includes an insulating layer with an etch selectivity with respect to the gap-fill insulating layer.

3. The method of claim 1, wherein the barrier layer is formed to have a thickness of about 50 Å to about 100 Å.

4. The method of claim 1, wherein the polishing process includes a chemical mechanical polishing (CMP) process.

5. The method of claim 4, wherein the polishing process includes:
a first polishing process of etching the gap-fill insulating layer until the height of the top surface of the gap-fill insulating layer from the bottom surface of the substrate reaches that of the barrier layer or slightly lower/higher;
a second polishing process of etching the gap-fill insulating layer and the barrier layer until they are removed; and
a third polishing process of etching until a top surface of the hard mask layer is exposed.

6. The method of claim 5, wherein the first polishing process is performed by using slurry that has a gap-fill insulating layer removing rate in a range from about 3000 Å/min to about 3500 Å/min and an etch selectivity of the gap-fill insulating layer to the barrier layer ranges from about 3:1 to about 4:1.

7. The method of claim 5, wherein the second and the third polishing process are performed by using slurry that has a gap-fill insulating layer removing rate in a range from about 3500 Å/min to about 4000 Å/min and an etch selectivity of the gap-fill insulating layer to the barrier layer ranges from about 30:1 to about 40:1.
